(19) United States
(12) Patent Application Publication
(10) Pub. No.: US 2025/0300116 A1
(43) Pub. Date: Sep. 25, 2025

(54) LIQUID METAL INTERCONNECTS WITH ANGLED WELL AND PIN FEATURES

(71) Applicant: Intel Corporation, Santa Clara, CA (US)

(72) Inventors: Saikat Mondal, Chandler, AZ (US); Zhichao Zhang, Chandler, AZ (US)

(73) Assignee: Intel Corporation, Santa Clara, CA (US)

(21) Appl. No.: 18/610,567

(22) Filed: Mar. 20, 2024

(51) Int. Cl. H01L 23/00

(52) U.S. Cl. CPC H01L 24/24; H01L 24/13; H01L 24/16; H01L 2224/13019; H01L 2224/1355; H01L 2224/1357; H01L 2224/16225; H01L 2224/24227; H01L 2224/244; H01L 2224/245; H01L 2924/15321

(57) ABSTRACT

Liquid metal (LM) interconnects have angled features to reduce reflection loss and/or insertion loss of signals sent across the interconnects. The LM interconnects may be used to couple two electronic components, e.g., to physically and electrically couple an IC device and a circuit board together. One component has an array of LM wells, and the second component has a corresponding array of pins. The LM wells have tapered shapes, e.g., tapered sidewalls with LM within the sidewalls. A cap layer along seals the wells to hold the LM inside the wells. The pins on the second component have a flared portion that widens in the direction of the second component and tapers in the direction of the tip. When a pin is inserted into a corresponding LM well, the tip and straight (e.g., cylindrical) sections may be within the LM well, while the flared portion remains within the cap layer.

### BACKGROUND

Electronic circuits fabricated on a wafer of semiconductor material, such as silicon, are commonly called integrated circuits (ICs). A wafer with ICs is typically cut into numerous individual dies. IC devices (e.g., dies) can be coupled together in a multi-die IC package to integrate features or functionality and to facilitate connections to other components, such as package substrates. An IC package may be integrated onto an electronic system, such as a consumer electronic system.

Circuit boards may be manufactured with contact pads for mating with IC packages. For example, a socket may be mated with a circuit board, and a processor or other IC component can then mate with the socket. Socket designs include, for example, pin grid array (PGA) and land grid array (LGA). Liquid metal sockets, where a metal pin is inserted into a well that includes a liquid metal material, can provide reliable connections, improved thermal management, and a wider range of form factors compared to other socket technologies. However, existing liquid metal sockets have limitations at high signal speeds.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-section of a first electronic component coupled to a second electronic component by a liquid metal stack.

FIGS. 2A and 2B illustrate an enlarged portion of the cross-section of FIG. 1 and an exploded view of a pin and well in the enlarged portion.

FIG. 3 is a cross-section of a first electronic component coupled to a second electronic component by a liquid metal stack with angled well and pin features, according to some embodiments of the present disclosure.

FIGS. 4A and 4B illustrate an enlarged portion of the cross-section of FIG. 3 and an exploded view of a pin and well in the enlarged portion, according to some embodiments of the present disclosure.

FIGS. 5A and 5B are top views of a wafer and dies that may be used in combination with liquid metal stack with angled well and pin features in accordance with any of the embodiments disclosed herein.

FIG. 6 is a cross-sectional side view of an IC device that may be used in combination with liquid metal stack with angled well and pin features in accordance with any of the embodiments disclosed herein.

FIG. 7 is a cross-sectional side view of an IC device assembly that may include or be used in combination with liquid metal stack with angled well and pin features in accordance with any of the embodiments disclosed herein.

FIG. 8 is a block diagram of an example computing device that may include or be used in combination with liquid metal stack with angled well and pin features in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Sockets are used to couple electronic components together. For example, a socket may be used to pair a hardware device, such as a graphics card, a sound card, a storage device, a wireless chip, an Ethernet chip, etc., to a circuit board, such as a motherboard, system board, logic board, backplane, etc. The socket may follow a bus communication standard, such as PCI (Peripheral Component Interconnect) Express. The next generation of PCI Express may have higher transfer rates per line, e.g., 128 gigatransfers/second (GT/s) or 64 Baud (Bd), enabling higher throughput compared to previous standards.

As noted above, liquid metal materials are used in some socket designs, e.g., in liquid metal wells into which a solid conductive pin is inserted. The electrical properties (e.g., high conductivity and low resistance) and mechanical properties (e.g., fluidity, reduced insertion load) of liquid metals, such as gallium (Ga)-based liquid metal alloy, makes such materials appealing for the design of interconnects. Unlike solid metals, liquid metal materials are naturally soft, which enables them to be easily dispensed, patterned, deformed, and even stretched to form desired structures. Compared to other technologies, such as LGA, liquid metal sockets can enable larger form factors with reduced load per pin, which can enable higher pin counts.

Previous liquid metal wells have cylindrical shapes. At large form factors, an array of cylindrical liquid metal wells can exhibit capacitance between the wells, which can lead to impedance discontinuity, particularly for higher frequency signals. This can lead to undesired signal reflections and reflection loss (RL), which refers to the reduction in signal strength caused by the reflection of a portion of the signal at the interconnect. Furthermore, in any interconnect structure, it is important to minimize insertion loss (IL), which refers to the amount of energy that a signal loses as it travels along a transmission line or across a connection. In liquid metal sockets, IL is also generally higher at higher frequency signals.

The liquid metal interconnects described herein have angled features to reduce RL and/or IL of signals sent across the interconnects. The liquid metal interconnects may be used to couple two electronic components, e.g., to physically and electrically couple an IC device and a circuit board together. A first of the electronic components has an array of liquid metal (LM) wells, and the second electronic component has a corresponding array of pins. The LM wells have tapered shapes, e.g., tapered sidewalls with LM within the sidewalls. The LM wells may taper towards the first electronic component, away from the side in which the pins are inserted. A cap layer along one side of the LM wells seals the wells to hold the LM inside the wells. A first dielectric material between the LM wells may have a relatively low dielectric constant (e.g., below 4, or below 3.5), while a second dielectric material in the cap layer may have a higher dielectric constant (e.g., above 4 or above 5).

The pins on the second electronic component have a flared portion that widens in the direction of the second electronic component and tapers in the direction of the tip. A straight (e.g., cylindrical) portion of the pin may extend between the flared portion and the tip, and the pin may narrow near the tip. The pins may be adhered to the second electronic component using solder balls. When a pin is inserted into a corresponding LM well, the tip and straight (e.g., cylindrical) sections may be within the LM well, while the flared portion remains within the cap layer.

The tapered shape of the LM wells reduces capacitance and, accordingly, RL in this layer of the interconnect. In the cap layer, the flaring shape of the pins can reduce impedance (e.g., resistance) and, accordingly, reduce IL in this layer of the interconnect. The shapes of the LM well and pin provides a relatively consistent impedance profile across the length of the interconnect compared to prior LM interconnects, which typically have a higher RL within the LM wells, and a higher IL within the cap layer. The improved impedance profile of the LM interconnects described herein increases their suitability particularly at higher frequencies (e.g., frequencies above 64 megabits/second).

The liquid metal interconnect stacks with angled well and pin features described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k or Dₖ) than silicon oxide. The terms “oxide,” “carbide,” “nitride,” etc. refer to compounds containing, respectively, oxygen, carbon, nitrogen, etc.

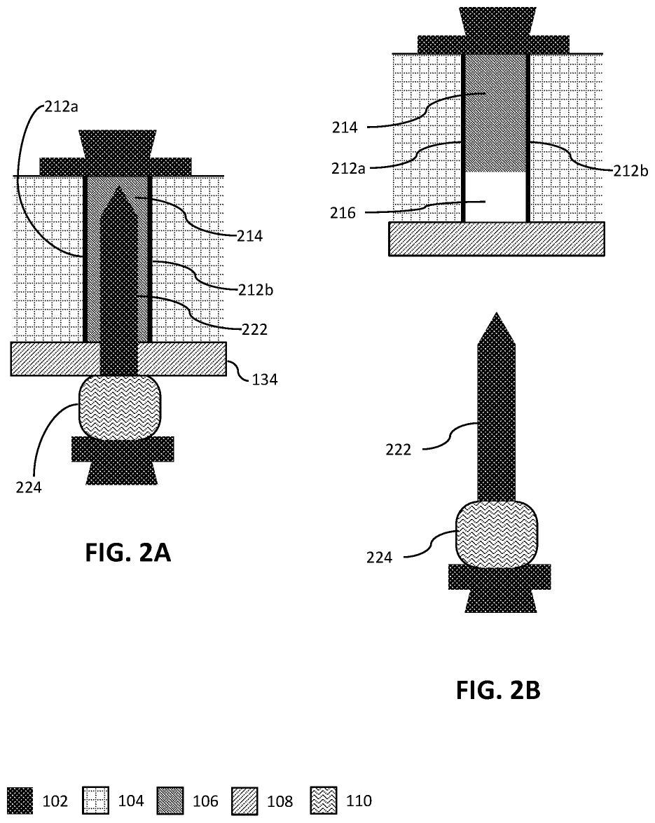

For convenience, if a collection of drawings designated with different letters are present, e.g., FIGS. 2A-2B, such a collection may be referred to herein without the letters, e.g., as “FIG. 2.”

### Example Liquid Metal Interconnect Stack

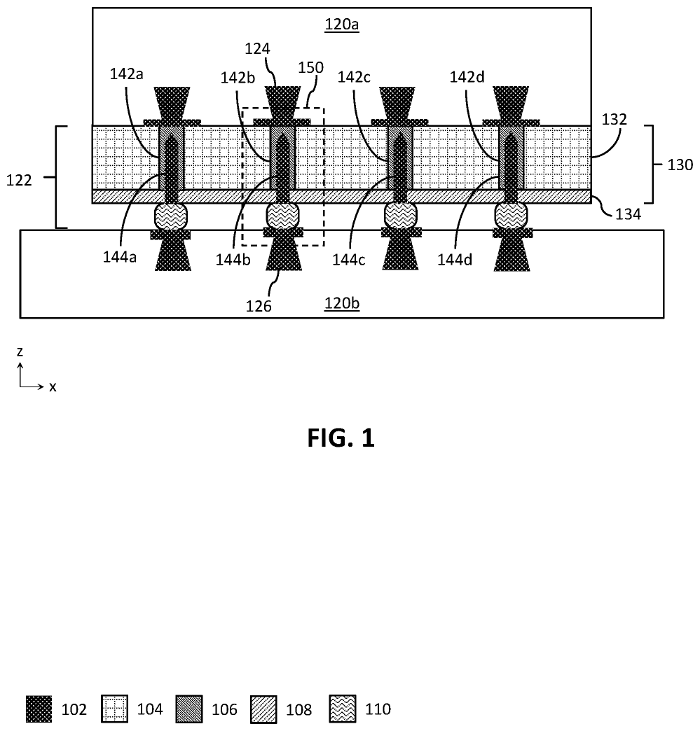

FIG. 1 is a cross-section of a first electronic component coupled to a second electronic component by a liquid metal stack. A number of elements referred to in the description of FIGS. 1-4 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show a conductive material 102, a first dielectric material 104, a LM 106, a second dielectric material 108, and solder 110.

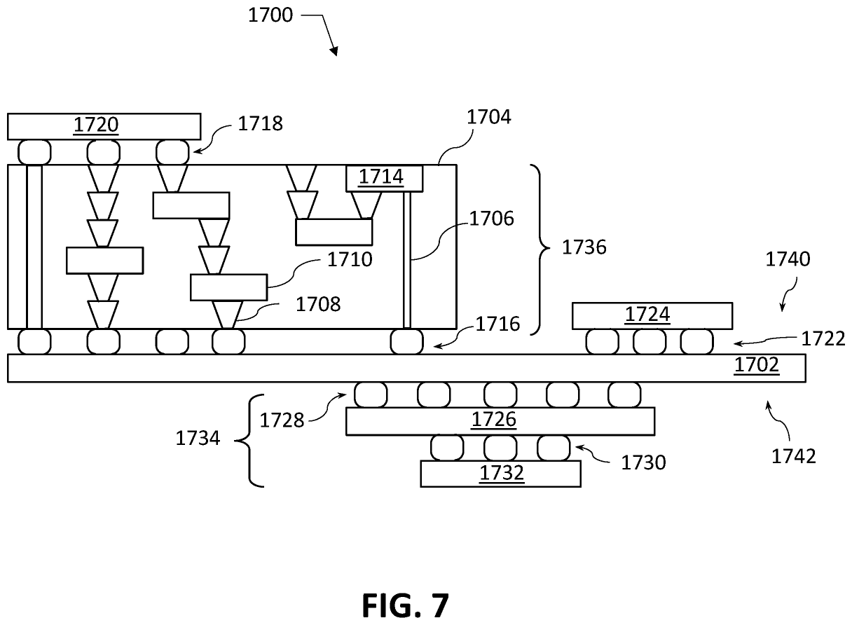

FIG. 1 illustrates two electronic components 120a and 120b that are coupled together at an interface region 122, also referred to as an interconnect region 122. The electronic component 120a may be an electronics package, which may refer to a self-contained carrier of one or more dice, where the dice are attached to the package substrate. The package may be encapsulated for protection, with integrated or wire-bonded interconnects between the dice and leads, pins or bumps located on the external portions of the package substrate. The package may contain a single die, or multiple dice, providing one or more specific functions. FIG. 7, described below, provides examples of electronics packages.

The electronic component 120b may be a circuit board, such as a printed circuit board (PCB). For example, the electronic component 120b may be a motherboard, a system board, a logic board, a mainboard, or a backplane. The circuit board provides sockets for coupling IC devices to the circuit board, forming a larger computing system. For example, the circuit board may provide one or more LGA and/or PGA sockets that can connect processors (e.g., CPUs) to the circuit board in desktop and server computers. Furthermore, the circuit board may provide additional interfaces or slots for additional devices. For example, the circuit board may include one or more PCI Express slots for coupling hardware components, such as graphics cards, network cards, storage devices, and other peripherals, to the circuit board. While a single electronic component 120a is illustrated as being coupled to the electronic component 120b, in other cases, multiple different IC devices (e.g., one or more CPUs, graphic cards, network cards, etc.) are coupled to the electronic component 120b. FIG. 7, described below, provides an example of circuit board.

Each of the electronic components 120a and 120b include conductive structures, e.g., the conductive structure 124 in the electronic component 120a and the conductive structure 126 in the electronic component 120a. The conductive structures in the electronic component 120a are coupled to the interconnect region 122, and in particular, to LM wells 142 in the interconnect region 122. The conductive structures in the electronic component 120b are also coupled to the interconnect region 122, and in particular, to pin assemblies 144 in the interconnect region 122. The illustrated conductive structures may be electronically coupled to other features (e.g., semiconductor devices, passive devices, wires, other interconnects, etc.) within the electronic components 120; details of the electronic components 120a and 120b are not shown in FIG. 1.

The interconnect region 122 includes an LM patch assembly 130 which is attached to the electronic component 120a. The LM patch assembly 130 includes a first layer 132 of the first dielectric material 104 and a second layer 134 of the second dielectric material 108, where the first layer 132 is between the electronic component 120a and the second layer 134. Liquid metal wells 142a, 142b, 142c, and 142d, referred to generally as LM wells 142, are formed in the first layer 132 of the first dielectric material 104. While four LM wells 142 are illustrated, the first layer 132 may include any number of LM wells 142. The LM wells may be formed in multiple rows, e.g., the row illustrated in the x-z cross section of FIG. 1, as well as one or more rows in front of and/or behind the illustrated cross-section.

The LM wells 142 contain the LM 106. The LM 106 may be any conductive material that is liquid at a desired operating temperature, e.g., room temperature, or a range of desired operating temperatures. In some embodiments, the LM 106 includes one or more of cesium, gallium, and rubidium. For example, the LM 106 is an alloy of gallium and indium or an alloy of gallium and tin. More generally, the LM 106 may include elements such as, but not limited to, gallium, rubidium, cesium, carbon, indium, tin, bromine, and/or oxygen. The LM 106 may be a eutectic that is an alloy having a melting point at or near room temperature.

The interconnect region 122 further includes four pin assemblies 144a, 144b, 144c, and 144d (generally referred to as pin assemblies 144) that are attached to the electronic component 120b. Each pin assembly includes a pin of the conductive material 102 and a ball of the solder 110 attaching the pin to the electronic component 120b. The pin assemblies 144 form a pin array. The number, size, and arrangement of pin assemblies in the pin array may generally correspond to the number, size, and arrangement of the LM wells 142, such that each pin assembly 144 couples with a corresponding LM well 142.

The conductive material 102 in the pin assemblies 144 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductive material 102 may include one or more electrically conductive alloys, oxides, or carbides of one or more metals. While FIG. 1 uses a single pattern for the conductive material 102 in the pin assemblies 144, electronic component 120a, and electronic component 120b, in some cases, the pin assemblies 144 may include a different conductive material from the electronic component 120a and/or electronic component 120b.

The solder 110 may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys.

FIG. 2A illustrates an enlarged portion 150 of FIG. 1, more clearly showing one of the LM wells 142 (here, the LM well 142b) and one of the pin assemblies 144 (here, the pin assembly 144b). FIG. 2B illustrates the pin assembly 144b and LM well 142b prior to inserting the pin assembly 144b into the LM well 142b.

Each pin assembly 144 includes a solder ball 224 and a pin 222 attached to the solder ball 224. When the electronic component 120a and electronic component 120b are coupled together, the pin 222 extends through the second layer 134 and into the filling 214 of the LM well 142, as shown in FIG. 2A. The solder ball 224 is under the second layer 134, e.g., the solder ball 224 is not inserted into the LM patch assembly 130.

The LM wells 142 each include sidewalls 212a and 212b and a filling 214 within the sidewalls 212; here, the liquid metal 106 fills the LM wells 142. In FIG. 2B, before the pin assembly 144 is inserted, the LM well 142 may have an unfilled space 216, e.g., air, that is displaced when the pin assembly 144 is inserted into the LM well 142.

In the example of FIGS. 1 and 2, the sidewalls 212 extend vertically, i.e., straight up and down, in the z-direction of the coordinate system shown. As noted above, this may lead to capacitance between adjacent LM wells 142, e.g., between the LM wells 142a and 142b, or between the LM wells 142b and 142c. In the example of FIGS. 1 and 2, the pins 222 extend vertically, e.g., having a generally cylindrical shape, and narrow at their tips. The narrow shape of the pins 222 may lead to IL across the interconnect region 122.

Example Liquid Metal Interconnect Stack with Tapered Well and Flared Pin

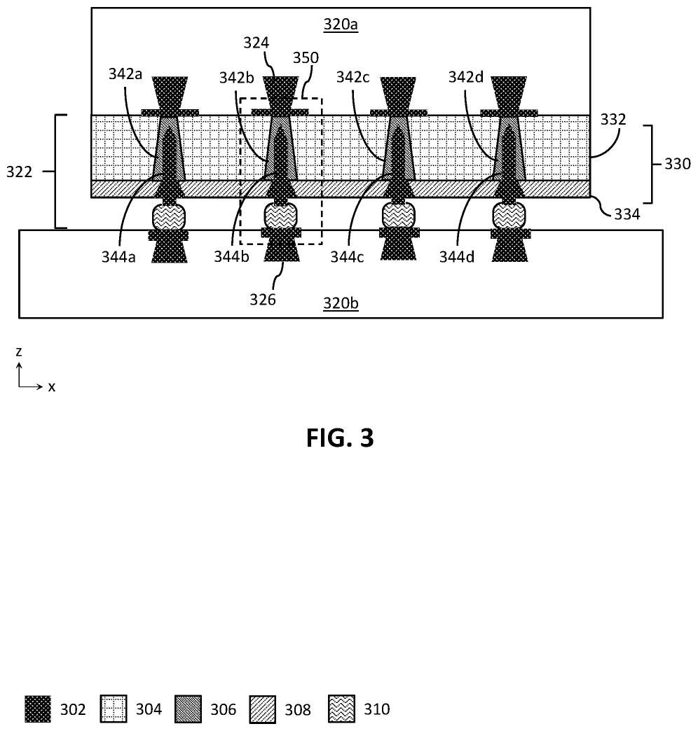

FIG. 3 is a cross-section of a first electronic component coupled to a second electronic component by a liquid metal stack with angled well and pin features, according to some embodiments of the present disclosure. The legend in FIG. 3 illustrates that FIG. 3 uses different patterns to show a conductive material 302, a first dielectric material 304, a LM 306, a second dielectric material 308, and solder 310.

FIG. 3 illustrates two electronic components 320a and 320b that are coupled together at an interface region 322, also referred to as interconnect region 322. The electronic component 320a may be an electronics package, similar to the electronic component 120a described with respect to FIG. 1. The electronic component 320b may be a circuit board, similar to the electronic component 120b described with respect to FIG. 1. Alternatively, the electronic component 320b may be an electronics package, while electronic component 320a is a circuit board. While a single electronic component 320a is illustrated as being coupled to the electronic component 320b, in other cases, multiple different IC devices (e.g., one or more CPUs, graphic cards, network cards, etc.) are coupled to the electronic component 320b, e.g., by multiple ones of the interface region 322 and/or different types of interconnects, e.g., as described with respect to FIG. 7.

Each of the electronic components 320a and 320b include conductive structures, e.g., the conductive structure 324 in the electronic component 320a and the conductive structure 326 in the electronic component 320a. The conductive structures in the electronic component 320a are coupled to the interconnect region 322, and in particular, to LM wells 342 in the interconnect region 322. The conductive structures in the electronic component 320b are also coupled to the interconnect region 322, and in particular, to pin assemblies 344 in the interconnect region 322. The illustrated conductive structures may be electronically coupled to other features (e.g., semiconductor devices, passive devices, wires, other interconnects, etc.) within the electronic components 320; details of the electronic components 320a and 320b are not shown in FIG. 3.

The interconnect region 322 includes the LM patch assembly 330, which is attached to the electronic component 320a. The LM patch assembly 330 includes a first layer 332 of the first dielectric material 304 and a second layer 334 of the second dielectric material 308, where the first layer 332 is between the electronic component 320a and the second layer 334. Liquid metal wells 342a, 342b, 342c, and 342d, referred to generally as LM wells 342, are formed in the first layer 332 of the first dielectric material 304. While four LM wells 342 are illustrated, the first layer 332 may include any number of LM wells 342. The LM wells may be formed in multiple rows, e.g., the row illustrated in the x-z cross section of FIG. 3, as well as one or more rows in front of and/or behind the illustrated cross-section.

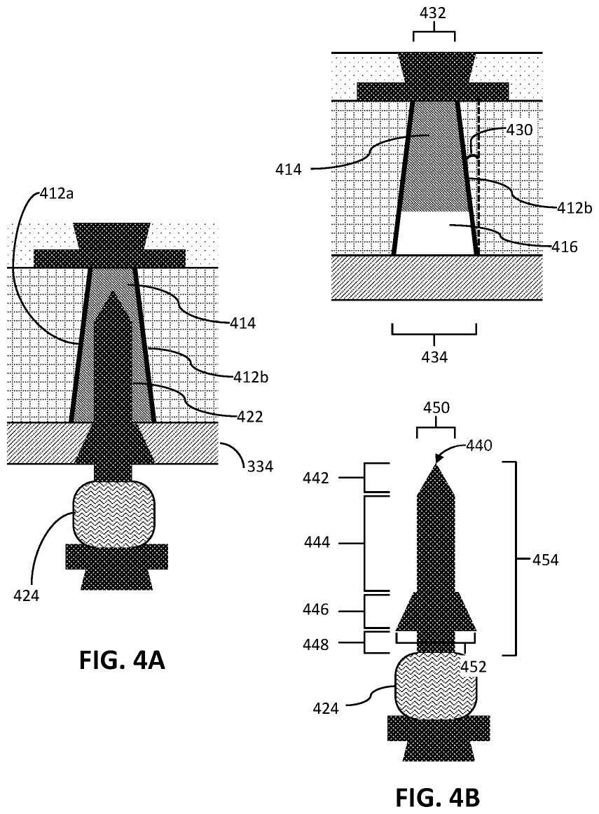

Unlike the LM wells 142 of FIGS. 1 and 2, the LM wells 342 taper in the direction of the electronic component 320a. The LM wells 342 contain the LM 306, which may be any of the LM materials described with respect to the LM 106. The second layer 334 is a cap layer along the bases of the LM wells 342. The second layer 334 may seal the LM wells 342 to hold the LM 306 inside the wells. An example LM well 342 is shown in greater detail in FIGS. 4A and 4B, described below.

The first layer 332 may have a height (measured in the z-direction) between 0.1 and 5 millimeters (mm). In some embodiments, the first layer 332 has a height around 0.6 mm, e.g., between 0.5 and 0.8 mm, or between 0.4 and 1 mm. The second layer 334 may have a height (measured in the z-direction) between 0.1 and 3 millimeters. In some embodiments, the second layer 334 has a height around 0.325 mm, e.g., between 0.3 and 0.35 mm, or between 0.2 and 0.4 mm. In some embodiments, the second layer 334 is thinner than the first layer 332.

Generally, the dielectric materials 304 and 308 of the LM patch assembly 330 may include any suitable dielectric materials. In some embodiments, the first dielectric material 304 has a lower dielectric constant than the second dielectric material 308. For example, the first dielectric material 304 may be a low-k dielectric (also referred to as a low Dₖ dielectric, where k or Dₖ refer to the dielectric constant), while the second dielectric material 308 is a high-k dielectric (also referred to as a high Dₖ dielectric). In some embodiments, the first dielectric material 304 has a dielectric constant that is less than 4, less than 3.9, less than 3.7, less than 3.5, less than 3.3, less than 3, less than 2.5, or some other value or range of values. In some embodiments, the second dielectric material 308 has a dielectric constant that is greater than 3.9, greater than 4, greater than 4.5, greater than 5, greater than 5.3, greater than 5.5, or some other value or range of values.

Examples of the low-k dielectric materials include, but are not limited to, silicon dioxide, carbon-doped oxide, silicon nitride, fused silica glass (FSG), and organosilicates such as silsesquioxane, siloxane, and organosilicate glass. Other examples of low-k dielectric materials include organic polymers such as polyimide, polynorbornenes, benzocyclobutene, perfluorocyclobutane, or polytetrafluoroethylene (PTFE). Still other examples of low-k dielectric materials include silicon-based polymeric dielectrics such as hydrogen silsesquioxane (HSQ) and methylsilsesquioxane (MSQ). Other examples of low-k materials include various porous dielectric materials, such as porous silicon dioxide or porous carbon-doped silicon dioxide, where voids or pores are created in a dielectric in order to reduce the overall dielectric constant of the layer.

Example high-k dielectric materials may include elements such as hafnium, silicon, oxygen, titanium, tantalum, lanthanum, aluminum, zirconium, barium, strontium, yttrium, lead, scandium, niobium, and zinc. Examples of high-k materials that may be used as the second dielectric material 308 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

In some embodiments, the LM patch assembly 330 includes one or more additional layers not shown in FIGS. 3 and 4. For example, the LM patch assembly 330 may include one or more adhesive layers, e.g., between the first layer 332 and the electronic component 320a, between the first layer 332 and second layer 334, or below the second layer 334.

The interconnect region 322 further includes four pin assemblies 344a, 344b, 344c, and 344d (generally referred to as pin assemblies 344) that are attached to the electronic component 320b. Each pin assembly includes a pin of the conductive material 302 and a ball of the solder 310 attaching the pin to the electronic component 320b. The pin assemblies 344 form a pin array. The number, size, and arrangement of pin assemblies in the pin array may generally correspond to the number, size, and arrangement of the LM wells 342, such that each pin assembly 344 couples with a corresponding LM well 342. Unlike the pin assemblies 144 of FIGS. 1 and 2, the pin assemblies 344 have a flared feature in the portion within the second layer 334 of the second dielectric material 308.

The conductive material 302 of the pin assemblies 344 and the electronic components 320 may include any of the conductive materials 102 described with respect to FIG. 1. While FIG. 3, like FIG. 1, uses a single pattern for the conductive material 302 in the pin assemblies 344, electronic component 320a, and electronic component 320b, in some embodiments, the pin assemblies 344 may include a different conductive material from the electronic component 320a and/or electronic component 320b. The solder 310 may include any appropriate solder material, including any of the solder materials described with respect to the solder 110 of FIG. 1.

In some embodiments, the interface region 322 is flipped relative to the two electronic components 320. In particular, an array of pin assemblies 344 may be coupled to the electronic component 320a (e.g., the IC package), while the LM wells 342 (and, more generally, the LM patch assembly 330) may be coupled to the electronic components 320b (e.g., the circuit board).

FIG. 4A illustrates an enlarged portion 350 of FIG. 3, more clearly showing one of the LM wells 342 (here, the LM well 342b) and one of the pin assemblies 344 (here, the pin assembly 344b). FIG. 4B illustrates the pin assembly 344b and LM well 342b prior to inserting the pin assembly 344b into the LM well 342b.

Each pin assembly 344 includes a solder ball 424 and a pin 422 attached to the solder ball 424. When the electronic component 320a and electronic component 320b are coupled together, the pin 422 extends through the second layer 334 and into the filling 414 of the LM well 342, as shown in FIG. 4A. The solder ball 424 is under the second layer 334; in this case, the solder ball 424 is not inserted into the LM patch assembly 330.

The LM wells 342 each include sidewalls 412a and 412b and a filling 414 within the sidewalls 412; here, the liquid metal 306 fills the LM wells 342. In FIG. 4B, before the pin assembly 344 is inserted, the LM well 342 may have an unfilled space 416, e.g., air, that is displaced when the pin assembly 344 is inserted into the LM well 342.

In the example of FIGS. 3 and 4, the sidewalls 412 extend at an angle, rather than vertically in the z-direction of the coordinate system. This causes the LM wells 342 to taper in width in a direction away from the electronic component 320b, i.e., a direction towards the electronic component 320a, or a direction away from the second layer 334 of the second dielectric material 308. The tapered sidewalls 412 may reduce capacitance between adjacent LM wells 342, e.g., between the LM wells 342a and 342b, or between the LM wells 342b and 342c, compared to the vertical design of the LM wells 142. FIG. 4B illustrates an angle 430 between the sidewall 412b and a vertical direction, e.g., a direction perpendicular to the interface 322. The angle 430 may be, in some embodiments, at least 3°, at least 5°, at least 7°, at least 10°, at least 15°, between 5° and 20°, or some other angle or range of angles.

The LM wells 342 may have a height, where height is measured in the z-direction, that the same as the first layer 332, i.e., the LM wells 342 may extend through the first layer 332. The height of the LM wells 342 may be between 0.1 and 5 mm. In some embodiments, the LM wells 342 have a height around 0.6 mm, e.g., between 0.5 and 0.8 mm, between 0.4 and 1 mm, etc. The tops of the LM wells 342 may have a width 432, where width is measured in the x-direction (as shown) or y-direction, that is between 50 and 500 microns. In some embodiments, the tops of the LM wells 342 have a width 432 around 150 microns, e.g., between 100 and 200 microns, or between 125 and 175 microns. The bases of the LM wells 342 may have a width 434, where width is measured in the x-direction (as shown) or y-direction, that is between 100 and 1000 microns. In some embodiments, the bases of the LM wells 342 have a width 434 around 400 microns, e.g., between 300 and 500 microns, or between 375 and 425 microns. In general, the width 434 at the bases of the LM wells 342, i.e., the width of the LM wells 342 at the interface with the second layer 334 of the second dielectric material 308, is greater than the width 432 at the tops of the LM wells 342, i.e., the width of the LM wells 342 at the interface with the electronic component 320a. In some embodiments, the width 434 is at least 1.5 times the width 432, at least twice the width 432, at least 2.5 times the width 432, or at least 3 times the width 432.

The LM wells 342 may have conical shape, e.g., a conical frustum, where the base and the top of each LM well 342 is circular. In some embodiments, the base and the top of each LM well 342 is an oval or other rounded shape. In other embodiments, each LM well 342 may be a frustum of a pyramid, where the base and the top of each LM well 342 is polygonal (e.g., square or rectangular). In some cases, the sidewalls 412 of the LM wells 342 may not appear as straight lines (as illustrated), but may be curved or bent.

FIG. 4B further illustrates the shape of the pins 422. The pin 422 has a tip 440 at an end opposite the solder ball 424. While the tip 440 is illustrated as a spike, in other embodiments, the tip 440 may be rounded off or squared off.

Moving downwards from the tip 440, the pin 422 has four portions 442, 444, 446, and 448. The uppermost portion 442 tapers in the direction of the tip 440. For example, the uppermost portion 442 may have a conical shape, with a circle at its base, or a pyramid shape, with a polygon (e.g., a square or rectangle) at its base. The tip 440 forms the apex of the uppermost portion 442. If the tip 440 is squared off or rounded off, the uppermost portion 442 may have a frustum shape or rounded conical or pyramid shape.

The next portion 444 has substantially vertical sides, i.e., the sides are straight up and down in the z-direction. The portion 444 may have an upper surface (i.e., the surface adjacent to the uppermost portion 442) and a lower surface (i.e., the surface adjacent to the flared portion 446, discussed below) having substantially the same size and shape, and x-y cross-sections between the upper surface and lower surface may also have substantially the same size and shape. In the x-z cross section shown, as well as the y-z cross section, the portion 444 has a substantially uniform width, e.g., the width 450. The portion 444 may have a circular shape in an x-y cross section, such that the portion 444 is cylindrical, or a polygonal shape in an x-y cross section, such that the portion 444 is a prism. In other embodiments, the portion 444 has an oval in an x-y cross section, or another round shape. The portion 442 and 444 may together have a height similar to or slightly less than the height of the first layer 332 of the first dielectric material 304, i.e., the height of the LM wells 342. For example, if the LM wells 342 have a height of 0.6 mm, the portions 442 and 444 may have a height of 0.5 mm or 0.55 mm.

The next portion 446, referred to as a flared or angled portion, has a greater width at a base surface than at a top surface. The flared portion 446 may have a frustum shape. The top and base of the flared portion 446 may be circles or other rounded shapes, or the top and base of the flare portion 446 may be polygons (e.g., squares or rectangles).

In FIG. 4B, the top surface of the flared portion 446, which abuts the base of the portion 444, has a width 450. The portion 444 and/or the base of the uppermost portion 442 may have the same width 450. The bottom surface or base of the flared portion 446, which abuts the top of the portion 448 has a width 452. The width 452 at the base of the flared portion 446 is greater than the width 450 at the top of the flared portion 446. The same relationship between widths may be observed in the y-z cross section. The width of the flared portion 446 may generally increase moving from the top surface to the bottom surface, e.g., in a direction away from the tip 440. Said another way, the flared portion 446 flares out in the direction of the solder ball 424, i.e., in the direction of the electronic component 320b. Said yet another way, the flared portion 446 tapers in width in the direction of the tip 440. The flared portion 446 may have a height similar to the height of the second layer 334 of the second dielectric material 308. For example, if the second layer 334 has a height of 0.3 mm, the flared portion 446 may have a height of 0.3 mm.

The lowermost portion 448 of the pin 422 is between the flared portion 446 and the solder ball 424. The lowermost portion 448 may have substantially vertical sides, a substantially uniform width (e.g., the width 450), and a consistent x-y cross section across its height, as described with respect to the portion 444. For example, the lowermost portion 448 may have a cylindrical or prism shape. The lowermost portion 448 couples the pin 422 to the solder ball 424.

When the pin assembly 344 is inserted into the LM patch assembly 330, the portions 442 and 444 are within the LM well 342. The flared portion 446 is within the second layer 334 of the second dielectric material 308; the flared portion 446 is not within the LM well 342. In some embodiments, an upper section of the flared portion 446 may be within the LM well 342, or a lower section of the portion 444 may be within the second layer 334. In the example shown in FIGS. 3 and 4, the lowermost portion 448 and solder ball 424 are not within the LM patch assembly 330 and are below the LM patch assembly 330. In some embodiments, an upper section of the lowermost portion 448 may be within the second layer 334, or a lower section of the flared portion 446 may be below the second layer 334.

The flared shape of the flared portion 446 of the pin assembly 344, along with a relatively high dielectric constant of the second dielectric material 308 in the second layer 334, may reduce impedance within the flared portion 446 compared to a straight pin shape, e.g., the pin shape of FIGS. 1 and 2. Overall, the effect of the tapered LM wells 342 and flared pin portions may provide a more consistent impedance profile across the interconnect region 322 compared to the design of FIGS. 1 and 2. This results in lower IL and lower RL across the interconnect region 322, particularly for higher frequency signals.

### Example Devices

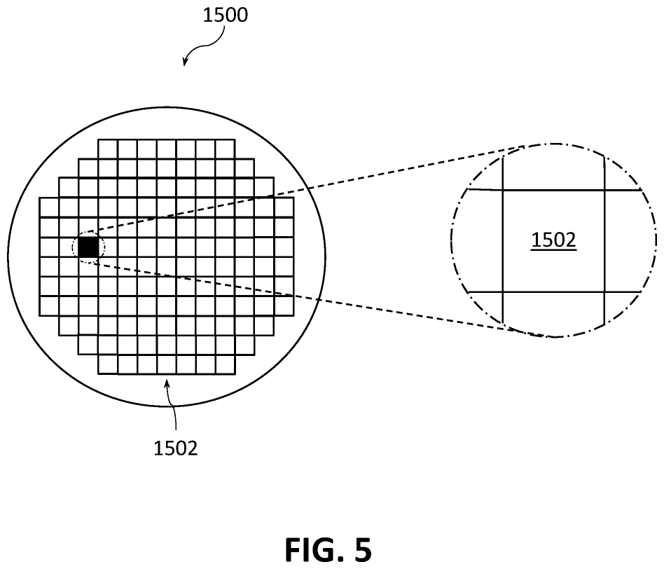

The circuit devices with one or more liquid metal interconnect stacks with angled well and pin features disclosed herein may be included in any suitable electronic device. FIGS. 5-8 illustrate various examples of apparatuses that may include or be used in combination with the liquid metal interconnect stacks with angled well and pin features.

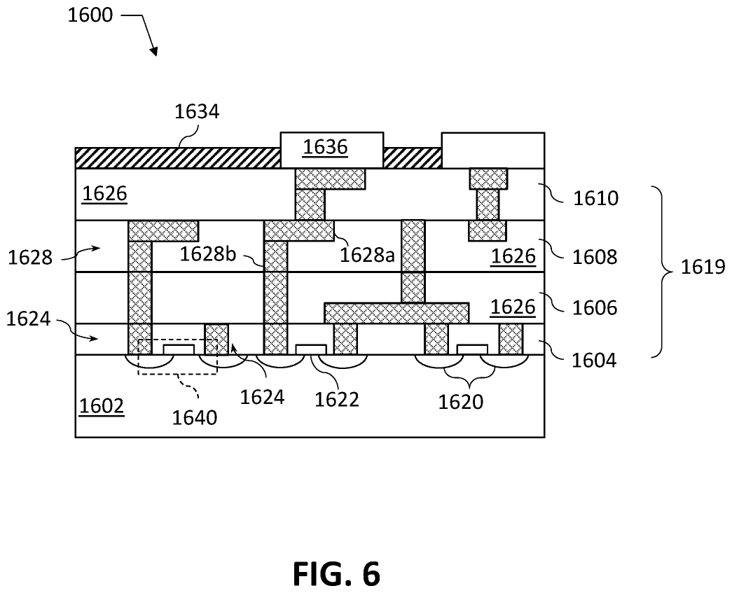

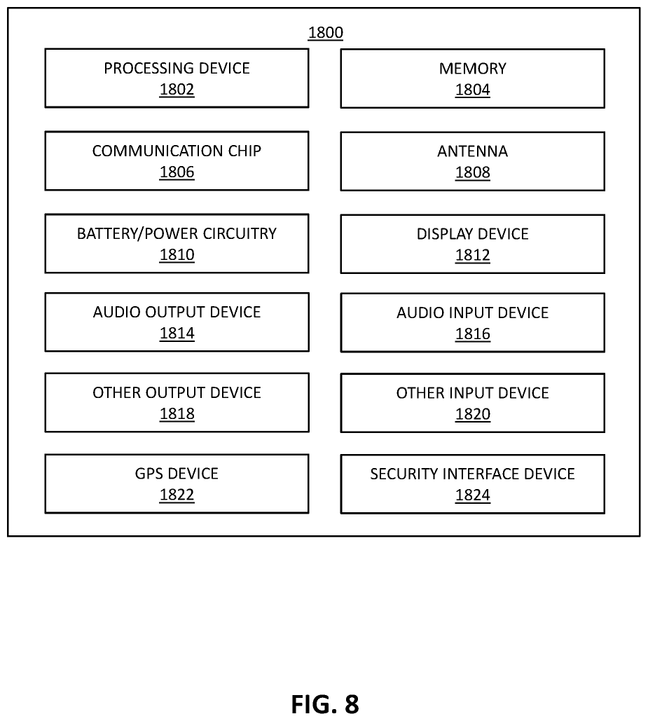

FIGS. 5A and 5B are top views of a wafer and dies that include one or more IC structures that may be used in combination with one or more liquid metal interconnect stacks with angled well and pin features in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., any embodiments of the IC structures described herein). After the fabrication of the semiconductor product is complete, the wafer 1500 may undergo a singulation process in which each of the dies 1502 is separated from one another to provide discrete “chips” of the semiconductor product. In particular, devices that include one or more transistors as disclosed herein may take the form of the wafer 1500 (e.g., not singulated) or the form of the die 1502 (e.g., singulated). The die 1502 may include one or more transistors (e.g., one or more of the transistors 1640 of FIG. 6, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

FIG. 6 is a cross-sectional side view of an IC device 1600 that may include or be used in combination with one or more liquid metal interconnect stacks with angled well and pin features in accordance with any of the embodiments disclosed herein. The IC device 1600 may be formed on a substrate 1602 (e.g., the wafer 1500 of FIG. 5A) and may be included in a die (e.g., the die 1502 of FIG. 5B). The substrate 1602 may be any substrate as described herein. The substrate 1602 may be part of a singulated die (e.g., the dies 1502 of FIG. 5B) or a wafer (e.g., the wafer 1500 of FIG. 5A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 6 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 6). Although a particular number of interconnect layers 1606-1610 is depicted in FIG. 6, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 6. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 6. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

FIG. 7 is a cross-sectional side view of an IC device assembly 1700 that may include components having or being associated with (e.g., being electrically connected by means of) one or more liquid metal interconnect stacks with angled well and pin features in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 5B), an IC device (e.g., the IC device 1600 of FIG. 6), or any other suitable component. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 7, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example computing device 1800 that may include or be used in combination with one or more liquid metal interconnect stacks with angled well and pin features in accordance with any of the embodiments disclosed herein. For example, any suitable ones of the components of the computing device 1800 may include a die (e.g., the die 1502 (FIG. 5B)). Any one or more of the components of the computing device 1800 may include, or be included in, an IC device 1600 (FIG. 6). Any one or more of the components of the computing device 1800 may include, or be included in, an IC device assembly 1700 (FIG. 7).

A number of components are illustrated in FIG. 12 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 8, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### SELECT EXAMPLES

The following paragraphs provide various examples of the embodiments disclosed herein.

Example 1 provides an assembly including a first electronic component; a second electronic component; and an interface between the first electronic component and the second electronic component, the interface including a well in the first electronic component, where the well tapers in width in a direction away from the second electronic component; and a pin coupled to the second electronic component, the pin having a tip, a first portion, and a second portion, the first portion between the tip and the second portion, where the second portion tapers in width in the direction of the tip, and the tip and first portion of the pin are within the well.

Example 2 provides the assembly of example 1, where the well contains a liquid metal that is surrounded by a side wall, the side wall tapering in the direction away from the second electronic component.

Example 3 provides the assembly of example 1 or 2, where the well is formed in a well layer, the well layer including a plurality of wells formed within a dielectric material having a dielectric constant less than 3.5.

Example 4 provides the assembly of any preceding example, the first electronic component further including a dielectric layer between the well and the second electronic component, where the second portion of the pin is within the dielectric layer.

Example 5 provides the assembly of example 4, where the dielectric layer includes a dielectric material having a dielectric constant greater than 4.

Example 6 provides the assembly of any preceding example, where the second portion of the pin is not within the well.

Example 7 provides the assembly of any preceding example, where the first portion of the pin has a substantially uniform width.

Example 8 provides the assembly of any preceding example, the pin further including a third portion between the first portion and the tip, the third portion tapering in the direction of the tip.

Example 9 provides the assembly of any preceding example, the pin further including an additional portion, the second portion between the first portion and the additional portion, the additional portion having a substantially uniform width.

Example 10 provides the assembly of any preceding example, further including a solder ball coupled between the pin and the second electronic component.

Example 11 provides an electronic component including a first layer including a first dielectric material; and a second layer including a second dielectric material and a plurality of liquid metal regions therein, one of the liquid metal regions tapering in a direction away from the first layer, and the one of the liquid metal regions electrically coupled to a conductive structure in the electronic component.

Example 12 provides the electronic component of example 11, where a portion of the first layer seals one of the plurality of liquid metal regions.

Example 13 provides the electronic component of example 11 or 12, where the one of the liquid metal regions has a conical shape.

Example 14 provides the electronic component of one of examples 11-13, where the one of the liquid metal regions has a first end and a second end opposite the first end, the second end adjacent to the first layer, the first end having a first width and the second end having a second width, the first width less than the second width.

Example 15 provides the electronic component of example 14, where the second width is at least twice the first width.

Example 16 provides the electronic component of one of examples 11-15, where an angle between a side wall of the liquid metal region and a direction perpendicular to an interface between the first layer and the second layer is at least 5°.

Example 17 provides the electronic component of one of examples 11-16, where an angle between a side wall of the liquid metal region and a direction perpendicular to an interface between the first layer and the second layer is at least 10°.

Example 18 provides an assembly (e.g., a pin assembly) including a solder ball; and a pin of a conductive material, the pin including a first portion over the solder ball, the first portion having a shape that flares out in a direction of the solder ball, the first portion having a first base and a first top; and a second portion over the first portion, the second portion having a second base and a second top, the second top coupled to the first top of the first portion, the second base and the second top having substantially a same shape.

Example 19 provides the assembly of example 18, the pin further including a conic solid having a third base and an apex, the third base of the conic solid coupled to the second top of the second portion.

Example 20 provides the assembly of example 18 or 19, where the second base and the second top of the second portion are round.

Example 21 provides the assembly of example 18 or 19, where the second base and the second top of the second portion are polygons.

Example 22 provides the assembly of one of examples 18-21, where the first base and a first top are round.

Example 23 provides the assembly of one of examples 18-21, where the first base and a first top are polygons.

Example 24 provides the assembly of one of examples 18-23, the pin further including a third portion between the solder ball and the second portion, the third portion coupled to the second base of the second portion.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An assembly comprising:
a first electronic component;
a second electronic component; and
an interface between the first electronic component and the second electronic component, the interface comprising:
a well in the first electronic component, wherein the well tapers in width in a direction away from the second electronic component; and
a pin coupled to the second electronic component, the pin having a tip, a first portion, and a second portion, the first portion between the tip and the second portion, wherein the second portion tapers in width in the direction of the tip, and the tip and first portion of the pin are within the well.

2. The assembly of claim 1, wherein the well contains a liquid metal that is surrounded by a side wall, the side wall tapering in the direction away from the second electronic component.

3. The assembly of claim 1, wherein the well is formed in a well layer, the well layer comprising a plurality of wells formed within a dielectric material having a dielectric constant less than 3.5.

4. The assembly of claim 1, the first electronic component further comprising a dielectric layer between the well and the second electronic component, wherein the second portion of the pin is within the dielectric layer.

5. The assembly of claim 4, wherein the dielectric layer comprises a dielectric material having a dielectric constant greater than 4.

6. The assembly of claim 1, wherein the first portion of the pin has a substantially uniform width.

7. The assembly of claim 1, the pin further comprising an additional portion, the second portion between the first portion and the additional portion, the additional portion having a substantially uniform width.

8. The assembly of claim 1, further comprising a solder ball coupled between the pin and the second electronic component.

9. An electronic component comprising:
a first layer comprising a first dielectric material; and
a second layer comprising a second dielectric material and a plurality of liquid metal regions therein, one of the liquid metal regions tapering in a direction away from the first layer, and the one of the liquid metal regions electrically coupled to a conductive structure in the electronic component.

10. The electronic component of claim 9, wherein a portion of the first layer seals one of the plurality of liquid metal regions.

11. The electronic component of claim 9, wherein the one of the liquid metal regions has a conical shape.

12. The electronic component of claim 9, wherein the one of the liquid metal regions has a first end and a second end opposite the first end, the second end adjacent to the first layer, the first end having a first width and the second end having a second width, the first width less than the second width.

13. The electronic component of claim 12, wherein the second width is at least twice the first width.

14. The electronic component of claim 9, wherein an angle between a side wall of the one of the liquid metal regions and a direction perpendicular to an interface between the first layer and the second layer is at least 5°.

15. An assembly comprising:
a solder ball; and
a pin of a conductive material, the pin comprising:
a first portion over the solder ball, the first portion having a shape that flares out in a direction of the solder ball, the first portion having a first base and a first top; and
a second portion over the first portion, the second portion having a second base and a second top, the second top coupled to the first top of the first portion, the second base and the second top having substantially a same shape.

16. The assembly of claim 15, the pin further comprising:
a conic solid having a third base and an apex, the third base of the conic solid coupled to the second top of the second portion.

17. The assembly of claim 15, wherein the second base and the second top of the second portion are round.

18. The assembly of claim 15, wherein the second base and the second top of the second portion are polygons.

19. The assembly of claim 15, wherein the first base and a first top are round.

20. The assembly of claim 15, the pin further comprising:
a third portion between the solder ball and the second portion, the third portion coupled to the second base of the second portion.
